(19) United States
(12) Patent Application Publication
(10) Pub. No.: US 2026/0013374 A1
(43) Pub. Date: Jan. 8, 2026

(54) DISPLAY PANEL AND PREPARATION METHOD THEREFOR, AND DISPLAY APPARATUS

(71) Applicant: Visionox Technology Inc., Kunshan (CN)

(72) Inventor: Junhui LOU, Kunshan (CN)

(73) Assignee: Visionox Technology Inc., Kunshan (CN)

(21) Appl. No.: 19/326,695

(22) Filed: Sep. 11, 2025

Related U.S. Application Data
(63) Continuation of application No. PCT/CN2023/137927, filed on Dec. 11, 2023.

(30) Foreign Application Priority Data
Mar. 31, 2023 (CN) 202310339856.0
Jun. 28, 2023 (CN) 202310773656.6

(51) Int. Cl. H10K 59/80; H10K 59/12; H10K 59/122

(52) U.S. Cl. CPC H10K 59/873; H10K 59/1201; H10K 59/122; H10K 59/80522

(57) ABSTRACT

Disclosed in the present application are a display panel and a preparation method therefor, and a display apparatus. The display panel includes a substrate, a light-emitting layer, a protective layer, and a conductive layer, where the light-emitting layer is formed on a side of the substrate and includes light-emitting units, each of the light-emitting units including a first electrode, a light-emitting functional layer and a second electrode stacked in a direction away from the substrate; the protective layer is formed on a side of the second electrode facing away from the substrate; and the conductive layer is formed on a side of the protective layer facing away from the second electrode, and the conductive layer is electrically connected to the second electrode. According to the display panel of the present application, the display uniformity of the display panel can be improved.

### CROSS-REFERENCE TO RELATED APPLICATIONS

The present application is a continuation of International Application No. PCT/CN2023/137927, filed on Dec. 11, 2023, which claims the priorities to Chinese Patent Application No. 202310339856.0, filed on Mar. 31, 2023, and entitled “DISPLAY PANEL AND DISPLAY APPARATUS”, and Chinese Patent Application No. 202310773656.6, filed on Jun. 28, 2023, and entitled “DISPLAY PANEL AND DISPLAY APPARATUS”, which are incorporated herein by reference in their entireties.

### FIELD

The present application relates to the field of display technology, and in particular, to a display panel and a preparation method therefor, and a display apparatus.

### BACKGROUND

With the advancement of display technology, the performance requirements for display devices are becoming increasingly stringent. However, in existing display panels, the problem of non-uniform display arises due to varying luminance of light-emitting units at different positions, which severely impacts the display uniformity of the display panels.

### SUMMARY

The embodiments of the present application provide a display panel and a preparation method therefor, and a display apparatus, which can improve display uniformity of the display panel.

An embodiment of the present application provides a display panel, including:
a substrate;
a light-emitting layer formed on a side of the substrate and including light-emitting units, each of the light-emitting units including a first electrode, a light-emitting functional layer and a second electrode stacked in a direction away from the substrate;
a protective layer formed on a side of the second electrode facing away from the substrate; and
a conductive layer formed on a side of the protective layer facing away from the second electrode, the conductive layer being electrically connected to the second electrode.

An embodiment of the present application further provides a display apparatus, including any one of the display panels according to the one embodiment of the present application.

An embodiment of the present application further provides a preparation method for a display panel, including: providing a substrate;
forming a light-emitting layer on a side of the substrate, the light-emitting layer including light-emitting units, where each of the light-emitting units includes a first electrode, a light-emitting functional layer and a second electrode stacked in a direction away from the substrate;
forming a protective layer on a side of the second electrode facing away from the substrate; and
forming a conductive layer on a side of the protective layer facing away from the second electrode, the conductive layer being electrically connected to the second electrode.

The display panel according to the present application includes a substrate, a light-emitting layer, a protective layer, and a conductive layer, where the light-emitting layer includes a first electrode, a light-emitting functional layer and a second electrode stacked in a direction away from the substrate; the protective layer and the conductive layer are sequentially stacked on a side of the second electrode facing away from the substrate; and the conductive layer includes a body portion and a light-transmitting portion, the light-transmitting portion being configured to transmit light emitted by the light-emitting unit, thereby ensuring display quality. By providing a body portion electrically connected to the second electrode, the resistance of a drive circuit for driving the light-emitting units may be reduced, thereby addressing the problem of non-uniform display due to varying luminance of the light-emitting units at different positions caused by excessive voltage loss during transmission arising from high resistance of the drive circuit. By adding a conductive layer, a resistor in parallel with the second electrode is formed, reducing the total resistance of the drive circuit, which in turn lowers the voltage loss during transmission and contributes to enhancing the luminance uniformity of the display panel. In addition, by providing the protective layer between the second electrode and the conductive layer, the damages to the second electrode and the light-emitting functional layer during the preparation of the conductive layer can be reduced, thereby reducing the impacts of the preparation process for the conductive layer on the yield of the display panel. Under the premise of the protective layer protecting the second electrode, etc., more options are available for selecting the preparation process for the conductive layer, facilitating the selection of a lower-cost preparation process. Moreover, the protective layer protects the second electrode and the light-emitting functional layer from moisture and oxygen during the preparation process, which contributes to improving the yield of the light-emitting units and the entire display panel.

### BRIEF DESCRIPTION OF THE DRAWINGS

FIG. 1 is a structural schematic diagram of a display panel according to an embodiment of the present application;

FIG. 2 is an enlarged view of part Q in FIG. 1;

FIG. 3 is a cross-sectional view along line P-P′ in FIG. 2;

FIG. 4 is another enlarged view of part Q in FIG. 1;

FIG. 5 is another cross-sectional view along line P-P′ in FIG. 2;

FIG. 6 is a top view of an isolation structure of a display panel according to an embodiment of the present application;

FIG. 7 is another cross-sectional view along line P-P′ in FIG. 2;

FIG. 8 is another cross-sectional view along line P-P′ in FIG. 2;

FIG. 9 is another cross-sectional view along line P-P′ in FIG. 2;

FIG. 10 is a cross-sectional view of another display panel according to an embodiment of the present application;

FIG. 11 is another cross-sectional view along line P-P′ in FIG. 2;

FIG. 12 is another cross-sectional view along line P-P′ in FIG. 2;

FIG. 13 is another cross-sectional view along line P-P′ in FIG. 2;

FIG. 14 is another cross-sectional view along line P-P′ in FIG. 2;

FIG. 15 is a structural schematic diagram of a display apparatus according to an embodiment of the present application.

### DETAILED DESCRIPTION OF THE EMBODIMENTS

The inventor has found through research that in existing display panels, the display panel includes a light-emitting layer, the light-emitting layer including light-emitting units. Each light-emitting unit includes a first electrode, a light-emitting functional layer and a second electrode that are stacked. The second electrodes of different light-emitting units each are either a single electrode disposed across the entire surface, or the second electrodes of different light-emitting units are independent of each other. To facilitate the transmission of light emitted by the light-emitting functional layer, the second electrode is made thinner, which increases the resistance thereof. This leads to a high resistance of a drive circuit of the display panel, potentially causing excessive voltage loss during transmission, resulting in varying luminance of the light-emitting units at different positions and ultimately leading to the problem of non-uniform display of the display panel. Based on the research on the above problems, provided is a display panel and a preparation method therefor, and a display apparatus, to improve the display uniformity of the display panel.

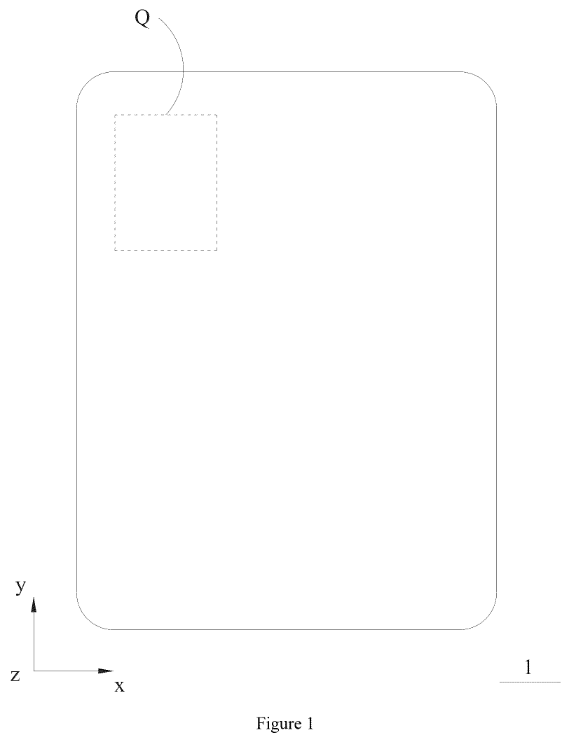

To better understand the present application, a display panel and a preparation method therefor, and a display apparatus according to embodiments of the present application are described in detail below with reference to FIGS. 1 to 15.

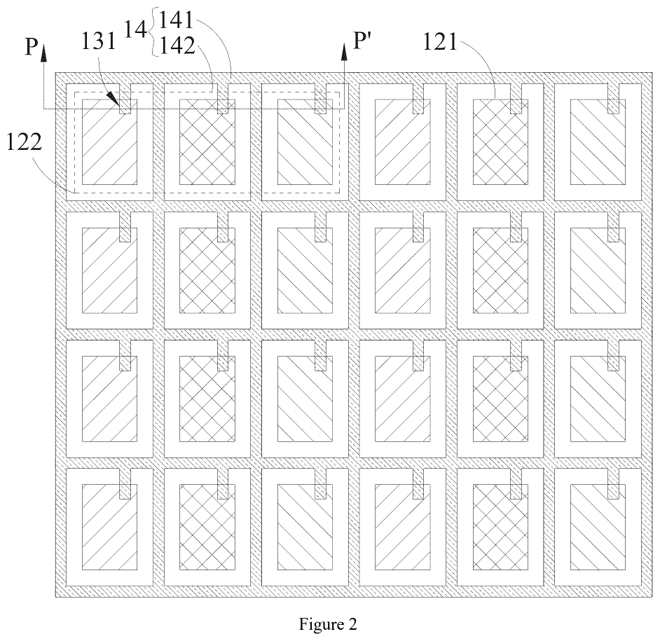

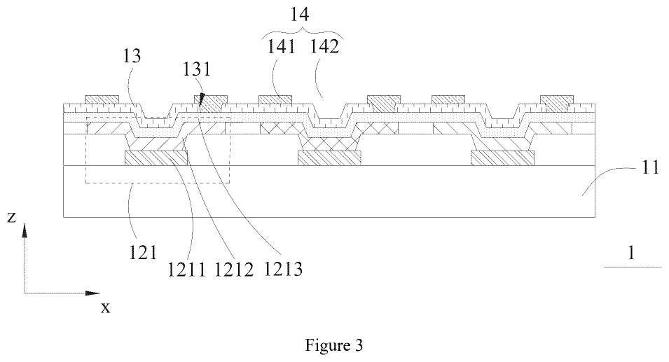

Referring to FIGS. 1 to 3, FIG. 1 is a structural schematic diagram of a display panel according to an embodiment of the present application. The display panel includes a first direction x, a second direction y perpendicular to the first direction x, and a third direction z perpendicular to both the first direction x and the second direction y, with the third direction z representing a thickness direction of the display panel. FIG. 2 is an enlarged view of part Q in FIG. 1. FIG. 3 is a cross-sectional view along line P-P′ in FIG. 2, and the cross section shown in the cross-sectional view is a cross section along the thickness direction of the display panel, i.e., the third direction z.

The embodiments of the present application provide a display panel 1, including a substrate 11, a light-emitting layer 12, a protective layer 13, and a conductive layer 14, where the light-emitting layer 12 is formed on a side of the substrate 11 and includes light-emitting units 121, each light-emitting unit 121 including a first electrode 1211, a light-emitting functional layer 1212 and a second electrode 1213 stacked in a direction away from the substrate 11. The protective layer 13 is formed on a side of the second electrode 1213 facing away from the substrate 11. The conductive layer 14 is formed on a side of the protective layer 13 facing away from the second electrode 1213, and the conductive layer 14 is electrically connected to the second electrode 1213.

The protective layer 13 is a light-transmitting film layer, which may be made of an inorganic material, particularly silicon nitride. A light-transmitting portion 142 exposes a part or all of the light-emitting units 121.

The display panel 1 according to the present application includes a substrate 11, a light-emitting layer 12, a protective layer 13, and a conductive layer 14, where the light-emitting layer 12 includes a first electrode 1211, a light-emitting functional layer 1212 and a second electrode 1213 stacked in a direction away from the substrate 11; and the protective layer 13 and the conductive layer 14 are sequentially stacked on a side of the second electrode 1213 facing away from the substrate 11. By providing the conductive layer 14 electrically connected to the second electrode 1213, the resistance of the drive circuit for driving the light-emitting units 121 may be reduced, thereby addressing the problem of non-uniform display due to varying luminance of the light-emitting units 121 at different positions caused by excessive voltage loss during transmission arising from a high resistance of the drive circuit. By adding the conductive layer 14, a resistor in parallel with the second electrode 1213 is formed, reducing the total resistance of the drive circuit, which in turn lowers the voltage loss during transmission and contributes to enhancing the luminance uniformity of the display panel 1. In addition, by providing the protective layer 13 between the second electrode 1213 and the conductive layer 14, the damages to the second electrode 1213 and the light-emitting functional layer 1212 during the preparation of the conductive layer 14 can be reduced, thereby reducing the impacts of the preparation process for the conductive layer 14 on the yield of the display panel 1. As the protective layer 13 protects the second electrode 1213, etc., more options are available for selecting the preparation process for the conductive layer 14, facilitating the selection of a lower-cost preparation process. Moreover, the protective layer 13 may protect the second electrode 1213 and the light-emitting functional layer 1212 from moisture and oxygen during the preparation process, which contributes to improving the yield of the light-emitting units 121 and the entire display panel 1.

In one embodiment, the substrate 11 may include a base substrate and a drive circuit layer formed on the base substrate and including a drive circuit. The drive circuit includes a drive device, a signal line, etc., and the drive device includes a transistor, a capacitor, etc., which is not particularly limited in the present application. The first electrode 1211 is formed on a side of the drive circuit layer facing away from the base substrate and is electrically connected to the drive circuit in the drive circuit layer.

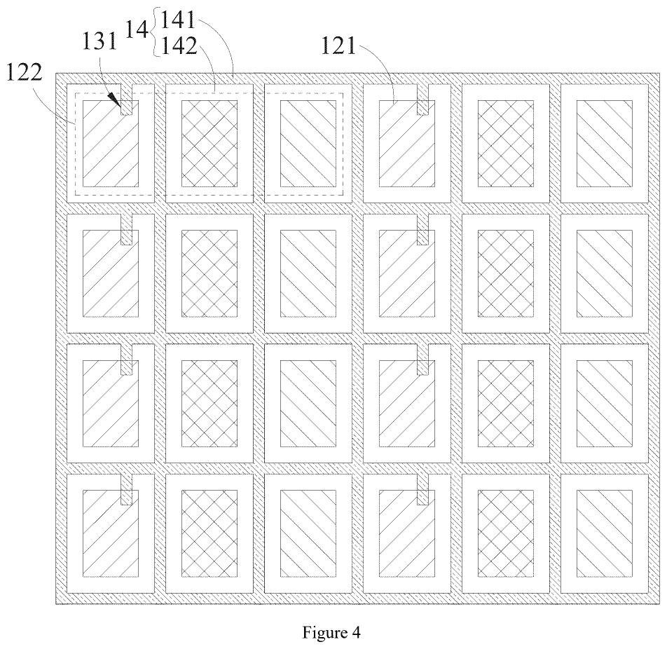

In one embodiment, as shown in FIGS. 2 and 4, the light-emitting layer 12 includes first light-emitting unit groups 122, each first light-emitting unit group 122 including the light-emitting units 121 of at least three colors, and the conductive layer 14 is electrically connected to the second electrode 1213 through a first via 131 running through the protective layer 13. The number of the first vias 131 corresponding to each first light-emitting unit group 122 is the same.

As shown in FIG. 2, each first light-emitting unit group 122 corresponds to three light-emitting units 121, and the first light-emitting unit group 122 corresponds to three first vias 131, and in one embodiment, each light-emitting unit 121 corresponds to one first via 131.

As shown in FIG. 4, FIG. 4 is another enlarged view of part Q in FIG. 1. Each first light-emitting unit group 122 corresponds to three light-emitting units 121, and the first light-emitting unit group 122 corresponds to one first via 131, and in one embodiment, one light-emitting unit 121 in the first light-emitting unit group 122 corresponds to one first via 131. The remaining light-emitting units 121 do not correspond to the first vias 131.

The conductive layer 14 is electrically connected to the second electrode 1213 through the first via 131 running through the protective layer 13. The orthographic projections of the first via 131 and the light-emitting unit 121 on the substrate 11 do not overlap, and the orthographic projections of the first via 131 and the light-transmitting portion 142 on the substrate 11 do not overlap. The correspondence between the first via 131 and the first light-emitting unit group 122 means that the orthographic projection of the first via 131 on the substrate 11 is located within the orthographic projection of the second electrode 1213 of each light-emitting unit 121 in the first light-emitting unit group 122 (that is, a part, corresponding to the first light-emitting unit group 122, of the second electrode 1213 provided across the entire layer) on the substrate 11.

The plurality of light-emitting units 121 in the light-emitting layer 12 may include light-emitting units 121 of at least three colors, in one embodiment, red light-emitting units 121, green light-emitting units 121, and blue light-emitting units 121, and may also include white light-emitting units 121, which is not particularly limited in the present application.

The first light-emitting unit group 122 may include light-emitting units 121 for forming one or more pixels, which is not particularly limited in the present application. In particular, each first light-emitting unit group 122 may correspond to one first via 131 or first vias 131, which is not particularly limited in the present application.

In one embodiment, by setting the number of first vias 131 corresponding to each light-emitting unit 121 to be the same, the first vias 131 in the display panel 1 can be regularly distributed, thereby improving the uniformity of opening positions of the display panel 1 and thus improving the uniformity of the display effect.

In one embodiment, as shown in FIG. 3, the orthographic projection of the second electrode 1213 on the substrate 11 covers the substrate 11.

In one embodiment, the conductive layer 14 includes a body portion 141 and a light-transmitting portion 142, the light-transmitting portion 142 corresponding to the light-emitting unit 121. The light-transmitting portion 142 is configured to transmit light emitted by the light-emitting unit 121 to ensure display quality.

In one embodiment, the orthographic projection of the second electrode 1213 on the substrate covers the substrate, thereby forming a planar second electrode 1213 disposed across the entire surface. By dividing the display panel 1 into first light-emitting unit groups 122, where the light-emitting units 121 in each first light-emitting unit group 122 have the same color and quantity, and the number of first vias 131 corresponding to each light-emitting unit 121 is the same, the repeatability of the display panel 1 is enhanced, contributing to an improved display effect. In particular, the enhanced repeatability is mainly reflected in the fact that, since the number of first vias 131 corresponding to each first light-emitting unit group 122 is the same, the impact of the first vias 131 on the pixel opening ratio of the light-emitting units 121 in different first light-emitting unit groups 122 is minimal, thereby helping to improve the uniformity of the display effect of the display panel 1. In addition, the display panel 1 is divided into first light-emitting unit groups 122, and the light-emitting units 121 in each first light-emitting unit group 122 have the same color and quantity. This ensures that the area difference of the second electrode 1213 corresponding to different first light-emitting unit groups 122, and the area difference of the body portion 141 corresponding to different first light-emitting unit groups 122 are small. The second electrode 1213 and the body portion 141 may easily form a coupling capacitor with other conductive layers 14 in the display panel 1, minimizing the influence variation of the corresponding coupling capacitors in different first light-emitting unit groups 122, thereby contributing to improved display uniformity.

In one embodiment, the light-emitting layer 12 includes second light-emitting unit groups, each second light-emitting unit group includes light-emitting units 121, and the light-emitting units 121 in the second light-emitting unit group have the same color; and the number of first vias 131 corresponding to different second light-emitting unit groups is different.

In particular, the display panel 1 may include three second light-emitting unit groups, in one embodiment, a second light-emitting unit group including red light-emitting units 121, a second light-emitting unit group including green light-emitting units 121, and a second light-emitting unit group including blue light-emitting units 121. The number of first vias 131 corresponding to different second light-emitting unit groups may be different, and the number and position of the first vias 131 are arranged according to the actual light emission requirements of the display panel 1, which is not particularly limited in the present application.

In one embodiment, the orthographic projection of the second electrode 1213 on the substrate 11 covers the substrate 11, or the second electrode 1213 of the light-emitting unit 121 in each second light-emitting unit group may be a continuous strip electrode, which is not particularly limited in the present application.

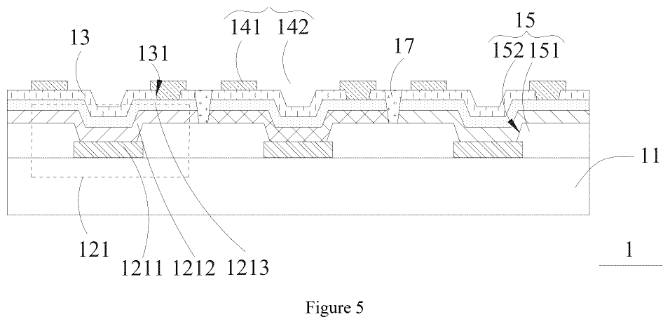

In one embodiment, as shown in FIG. 5, FIG. 5 is another cross-sectional view along line P-P′ in FIG. 2. The second electrodes 1213 of the adjacent light-emitting units 121 are spaced apart. The body portion 141 is electrically connected to the second electrode 1213 through first vias 131 running through the protective layer 13, the first vias 131 corresponding to the second electrodes 1213 on a one-to-one basis.

In one embodiment, the second electrodes 1213 of the adjacent light-emitting units 121 are spaced apart, that is, different second electrodes 1213 are independent of each other and are not continuous. The body portion 141 of the conductive layer 14 is electrically connected to the second electrode 1213 through the first via 131 running through the protective layer 13, and each second electrode 1213 is electrically connected to the body portion 141. Therefore, the body portion 141 and the second electrode 1213 may be connected in parallel to reduce the resistance of the drive circuit of each light-emitting unit 121, improving the luminance uniformity of each light-emitting unit 121. In addition, each independent second electrode 1213 may be electrically connected via the conductive layer 14, enabling all second electrodes 1213 to be energized when the conductive layer 14 is energized, simplifying the wiring in the display panel 1. Moreover, since the body portion 141 is electrically connected to the second electrode 1213 through the first via 131, this connection method is highly reliable, ensuring a stable power supply to each second electrode 1213.

In one embodiment, power supply to the conductive layer 14 may be realized by connecting the conductive layer 14 to a driver chip in the display panel 1. The conductive layer 14 may be connected to the driver chip via a connection line, and the connection line may be at least partially located in a peripheral circuit of the display panel 1, thereby minimizing the impact on the display effect of an active area.

In one embodiment, the conductive layer 14 includes a body portion 141 and a light-transmitting portion 142, the light-transmitting portion 142 corresponding to the light-emitting unit 121 and being configured to transmit light emitted by the light-emitting unit 121. The body portion 141 overlaps an edge of the second electrode 1213, and the body portion and the second electrode are electrically connected.

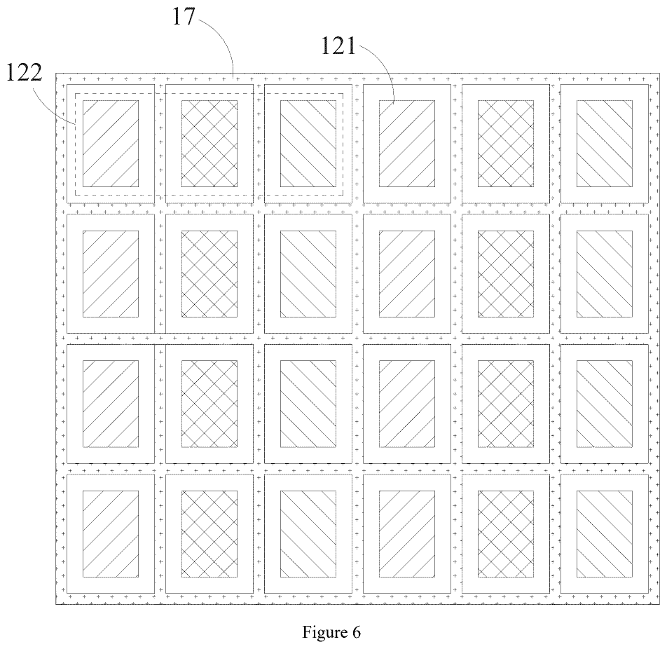

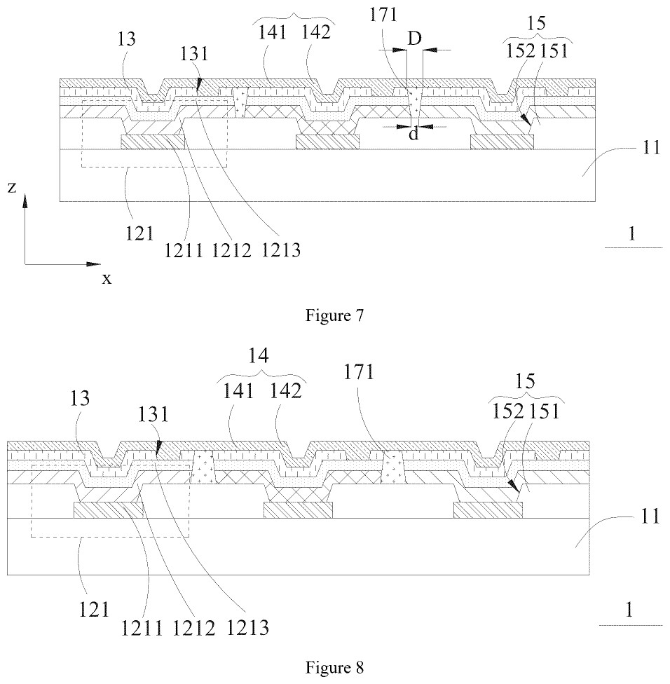

In one embodiment, as shown in FIGS. 6 and 7, FIG. 6 is a top view of an isolation structure of a display panel according to an embodiment of the present application, and FIG. 7 is another cross-sectional view along line P-P′ in FIG. 2. The display panel 1 further includes a pixel defining layer 15 and an isolation structure 17. The pixel defining layer 15 is formed on a side of the first electrode 1211 facing away from the substrate 11, and includes a pixel defining portion 151 and pixel openings 152, each of the pixel openings 152 being configured to expose the first electrode 1211, and the light-emitting units 121 corresponding to the pixel openings 152 on a one-to-one basis.

The second electrodes 1213 are spaced apart from and independent of each other. The second electrodes 1213 correspond to the pixel openings 152 on a one-to-one basis, and in each pair of the second electrode 1213 and the pixel opening 152 corresponding to each other, the orthographic projection of the second electrode 1213 on the substrate 11 covers the orthographic projection of the pixel opening 152 on the substrate 11.

The isolation structure 17 is formed on the side of the pixel defining portion 151 facing away from the substrate 11, and is positioned between two adjacent pixel openings 152.

In one embodiment, by providing the isolation structure 17, the light-emitting units 121 of different colors may be prepared separately and are independent of each other. In particular, the consecutive arrangement of the light-emitting functional layer 1212 between adjacent light-emitting units 121 may cause lateral crosstalk, leading to unintended light emission from adjacent light-emitting units 121, which affects the display quality. By independently providing the light-emitting units 121, the problem of lateral crosstalk between adjacent light-emitting units 121 can be mitigated, thereby improving the display quality of the display panel 1.

The pixel defining layer 15 includes at least a first pixel opening 1521, a second pixel opening 1522, and a third pixel opening 1523. In particular, when the display panel 1 includes light-emitting units 121 of three colors, the first pixel opening 1521 is configured to form a red light-emitting unit 121, the second pixel opening 1522 is configured to form a green light-emitting unit 121, and the third pixel opening 1523 is configured to form a blue light-emitting unit 121. When the display panel 1 further includes a white light-emitting unit 121, the pixel defining layer 15 may further include a fourth pixel opening configured to form the white light-emitting unit 121.

When the display panel 1 includes the isolation structure 17, the light-emitting units 121 of each color may first be prepared across the entire layer and then patterned, thereby eliminating the need for a mask, which contributes to reducing costs. The light-emitting units 121 of different colors are prepared in different sequences. In the process of patterning the subsequently prepared light-emitting units 121, the isolation structure 17 may be used for isolation, thereby improving the yield of the patterning process and reducing the impacts of patterning on the yield of the light-emitting units 121. The specific preparation process includes the following steps.

At step S100, a first electrode layer is formed on a side surface of a substrate 11, the first electrode layer including first electrodes 1211.

At step S200, a pixel defining layer 15 is formed on a side of the first electrode 1211 facing away from the substrate 11, the pixel defining layer 15 including a pixel defining portion 151 and a first pixel opening 1521 exposing the first electrode 1211, where the pixel defining portion 151 covers the substrate 11 and an edge of the first electrode 1211.

At step S300, an isolation structure 17 is formed on a side of the pixel defining portion 151 facing away from the substrate 11, the isolation structure 17 being positioned between two adjacent first pixel openings 1521.

At step S400, a red light-emitting functional layer 1212, a second electrode layer, and a protective layer 13 are sequentially formed across the entire layer, and then patterned to retain a part corresponding to the first pixel opening 1521 (that is, the part located between the isolation structures 17 surrounding the first pixel opening 1521), while parts corresponding to the second pixel opening 1522 and the third pixel opening 1523 are removed to expose the second pixel opening 1522 and the third pixel opening 1523. Thus, the light-emitting functional layer 1212 and the second electrode 1213 of the red light-emitting unit 121 are formed.

At step S500, a green light-emitting functional layer 1212, a second electrode layer, and a protective layer 13 are sequentially formed across the entire layer, and then patterned to retain a part corresponding to the second pixel opening 1522 (that is, the part located between the isolation structures 17 surrounding the second pixel opening 1522), while parts corresponding to the first pixel opening 1521 and the third pixel opening 1523 are removed to expose the first pixel opening 1521 and the third pixel opening 1523. Thus, the light-emitting functional layer 1212 and the second electrode 1213 of the green light-emitting unit 121 are formed.

At step S600, a blue light-emitting functional layer 1212, a second electrode layer, and a protective layer 13 are sequentially formed across the entire layer, and then patterned to retain a part corresponding to the third pixel opening 1523 (that is, the part located between the isolation structures 17 surrounding the third pixel opening 1523), while parts corresponding to the first pixel opening 1521 and the second pixel opening 1522 are removed to expose the first pixel opening 1521 and the second pixel opening 1522. Thus, the light-emitting functional layer 1212 and the second electrode 1213 of the blue light-emitting unit 121 are formed.

At step S700, a first via 131 is formed on the protective layer 13, misaligned with the pixel opening 152 and opposite to the second electrode 1213.

At step S800, a conductive layer 14 is formed on a side of the protective layer 13 facing away from the substrate 11, where the conductive layer 14 includes a body portion 141 and a light-transmitting portion 142 for exposing the light-emitting unit 121, and the body portion 141 is electrically connected to the second electrode 1213.

The above embodiment enables the preparation of light-emitting units 121 without the use of a precision mask, thereby reducing manufacturing costs. Moreover, the light-emitting units 121 are independent of each other, which reduces crosstalk between adjacent light-emitting units 121, and allows for independent package of the light-emitting units 121, improving package reliability. In one embodiment, the isolation structure 17 mainly serves to reduce the probability of an etching solution entering the red light-emitting unit 121 during the patterning of the red light-emitting functional layer 1212, the second electrode layer, and the protective layer 13 in S500, and to reduce the probability of an etching solution entering the red light-emitting unit 121 and the green light-emitting unit 121 during the patterning of the blue light-emitting functional layer 1212, the second electrode layer, and the protective layer 13 in S600. Moreover, the isolation structure isolates adjacent light-emitting units 121, thereby improving crosstalk.

In one embodiment, as shown in FIG. 7, a first cross-section 171 of the isolation structure 17 along the thickness direction of the display panel may be rectangular, upright trapezoidal, or inverted trapezoidal in shape, where the thickness direction is the third direction z in the display panel.

In particular, as shown in FIG. 7, when the first cross-section 171 is inverted trapezoidal in shape, the isolation structure partitions the light-emitting functional layer at the edges, ensuring that the light-emitting functional layer does not contact the isolation structure at the edge facing the isolation structure. This improves the coverage effect of the subsequent encapsulation layer on the edge facing the isolation structure, thereby further enhancing the encapsulation reliability.

The shape of the first cross-section 171 is not limited to the inverted trapezoid described above, and the first cross-section 171 may be in any shape in which the length D at the end away from the substrate 11 is greater than the length d at the end close to the substrate 11, along a direction parallel to the substrate 11, while still achieving the above effects. The present application does not impose any specific limitations.

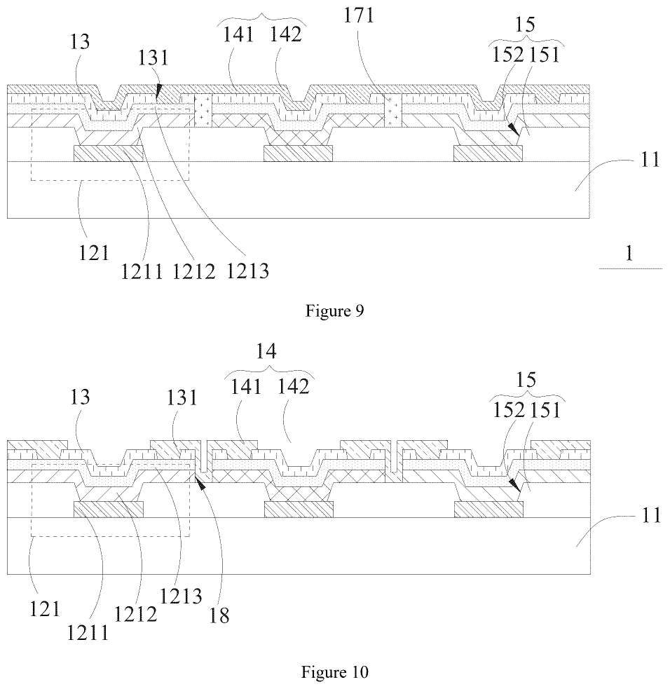

As shown in FIGS. 8 and 9, FIG. 8 is another cross-sectional view along line P-P′ in FIG. 2, and FIG. 9 is another cross-sectional view along line P-P′ in FIG. 2. When the first cross-section 171 is upright trapezoidal or rectangular in shape, the transition effect of the film layer on the side of the isolation structure facing away from the substrate is improved at a side surface of the isolation structure, thereby reducing the probability of bubble formation in the film layer. When bubbles are formed in the film layer, gas overflow from the bubbles due to high temperatures in subsequent process steps may affect the yield of the display panel. The light-emitting layer needs to be isolated from moisture and oxygen, and gas overflow may cause oxygen in the gas to negatively impact the performance of the light-emitting layer. Moreover, gas overflow may lead to cracks in subsequent film layers, posing a risk of package failure. The above design reduces the probability of bubble formation, thereby improving the yield of the display panel. Moreover, the preparation process is simplified, which contributes to enhancing the preparation yield of the isolation structure and reducing preparation costs.

The isolation structure 17 may be made of a conductive material, such as metal, or an insulating material, which is not particularly limited in the present application.

In one embodiment, the second electrodes 1213 are independent of each other, making it difficult to supply power to each second electrode 1213. When the second electrodes 1213 are electrically connected and powered synchronously via the isolation structure 17, there may be a problem of low connection reliability. The main reasoning is that the light-emitting functional layer 1212 is easily formed on a side wall of the isolation structure 17 during the preparation process, thereby blocking the side wall of the isolation structure 17 and avoiding a reliable electrical connection between the subsequent second electrode 1213 and the isolation structure 17. This hinders the powering of the second electrode 1213. Therefore, the present application provides a cathode synchronous power supply method with improved reliability. In the display panel 1 according to the present application, the electrical connection of each second electrode 1213 is realized by the conductive layer 14, and the body portion 141 of the conductive layer 14 is electrically connected to the second electrode 1213 through the first via running through the protective layer 13, ensuring high connection reliability. This enables synchronous power supply to each second electrode 1213 with a high yield of power supply, which contributes to improving the reliability of the display panel 1.

In one embodiment, as shown in FIG. 10, the display panel 1 further includes a pixel defining layer 15. The pixel defining layer 15 is formed on a side of the first electrode 1211 facing away from the substrate 11, and includes a pixel defining portion 151 and pixel openings 152, each of the pixel openings 152 being configured to expose the first electrode 1211, and the light-emitting units 121 corresponding to the pixel openings 152 on a one-to-one basis. An isolation gap 18 is formed between the adjacent light-emitting units 121, and exposes part of the pixel defining portion 151. The orthographic projection of the protective layer 13 on the substrate 11 does not overlap with the orthographic projection of the isolation gap 18 on the substrate 11. The body portion 141 extends into the isolation gap 18.

In one embodiment, the isolation gap 18 is provided between the adjacent light-emitting units 121, and the isolation gap 18 exposes part of the pixel defining portion 151, thereby ensuring the mutual independence of the adjacent light-emitting units 121 and improving the problem of crosstalk between the adjacent light-emitting units 121. The protective layer 13 and the conductive layer 14 are sequentially stacked on the side of the second electrode 1213 facing away from the substrate 11. The orthographic projection of the protective layer 13 on the substrate 11 does not overlap with the orthographic projection of the isolation gap 18 on the substrate 11, ensuring synchronous patterning of the protective layer 13 and an underlying film layer. The protective layer 13 can protect the underlying film layer, reducing the probability of damage to the underlying film layer during the subsequent preparation process. The conductive layer 14 includes a body portion 141 and a light-transmitting portion 142, the light-transmitting portion 142 being configured to transmit light emitted by the light-emitting unit 121 to ensure display quality. The body portion 141 is configured to connect the second electrodes 1213 of each light-emitting unit 121, and the body portion 141 extends into the isolation gap 18, increasing the area of the body portion 141. After the body portion 141 is connected to the second electrode 1213, the two are provided in parallel, reducing the resistance of the drive circuit of the light-emitting unit 121. The larger area of the body portion 141 improves the effect of reducing resistance, which in turn reduces voltage loss during transmission, lowers the power consumption of the display panel 1, and enhances the performance of the display panel 1. It also helps to address the problem of non-uniform display due to varying luminance of the light-emitting units 121 at different positions caused by excessive voltage loss during transmission arising from high resistance of the drive circuit.

In one embodiment, as shown in FIG. 10, the body portion 141 extends into the isolation gap 18 and contacts the edge of the second electrode 1213.

In one embodiment, the body portion 141 contacts the edge of the second electrode 1213 exposed by the isolation gap 18, which further increases the contact area between the body portion 141 and the second electrode 1213, thereby further reducing the resistance of the drive circuit. At the same time, this improves the electrical connection reliability between the body portion 141 and the second electrode 1213, protects the edge of the light-emitting unit 121 exposed by the isolation structure 17, and isolates the light-emitting unit 121 from corrosion by moisture, oxygen, etc. It also reduces the impact of subsequent processes on the light-emitting unit 121, helping to improve the yield of the light-emitting unit 121 and, consequently, the yield of the display panel 1.

In one embodiment, as shown in FIG. 7, the conductive layer 14 includes a body portion 141 and a light-transmitting portion 142, the light-transmitting portion 142 corresponding to the light-emitting unit 121 and being configured to transmit light emitted by the light-emitting unit 121. The light-transmitting portion 142 is integrally and consecutively formed with the body portion 141, and the conductive layer 14 is made of a transparent conductive material.

In one embodiment, the conductive layer 14 is made of a transparent conductive material, that is, the conductive layer 14 is light-transmissive. As a result, the conductive layer 14 may be prepared across the entire layer, with the light-transmitting portion 142 and the body portion 141 being located in the same layer and consecutively provided. The part of the conductive layer 14 corresponding to the light-emitting unit 121 is the light-transmitting portion 142, while the other part is the body portion 141.

When the display panel 1 includes the above isolation structure 17, the part of the conductive layer 14 corresponding to the isolation structure 17 may be located on the side of the isolation structure 17 facing away from the substrate 11. The conductive layer 14 may then be disposed across the entire surface by adjusting the sizes of the isolation structure 17 and the protective layer 13 along the thickness direction of the substrate 11. In one embodiment, the conductive layer 14 is discontinuous at a position corresponding to the isolation structure 17 along the thickness direction of the substrate 11, which is not particularly limited in the present application.

The transparent conductive material may include indium tin oxide, indium zinc oxide, etc., which is not particularly limited in the present application. The above conductive layer 14 is typically prepared using a plasma film forming process. This plasma film forming process may easily affect the yield of the light-emitting unit 121. However, due to the formation of the protective layer 13, the protective layer 13 serves to isolate moisture and oxygen, thereby protecting the light-emitting unit 121 and improving the yield of the light-emitting unit 121.

In one embodiment, as shown in FIG. 5, the light-transmitting portion 142 includes a through hole through the body portion 141 along a thickness direction of the body portion 141, the through hole being configured to transmit light emitted by the light-emitting unit 121.

In one embodiment, the conductive layer 14 has a mesh structure, with through holes provided to ensure the luminance of the light-emitting unit 121 and the pixel opening ratio, thereby improving the light transmittance of the display panel 1.

In this case, the conductive layer 14 is made of at least one of a metal and a transparent metal oxide material, which is not particularly limited in the present application.

When the conductive layer 14 is made of a metal, the metal may include silver or a mixture of silver and magnesium. The material of the conductive layer 14 may be the same as that of the second electrode 1213, which can improve the contact between the conductive layer 14 and the second electrode 1213, thereby enhancing the connection reliability. Moreover, when the conductive layer 14 is made of a metal, the resistivity is lower, thereby further reducing the resistance of the drive circuit. Finally, when the above materials are used, an evaporation coating process may be employed for preparation. The evaporation coating process has less impact on the second electrode 1213 located below, helping to ensure the yield of the second electrode 1213.

In one embodiment, the conductive layer 14 may be made of molybdenum, aluminum, titanium, or a mixture thereof, and may be prepared using a vacuum coating process. The vacuum coating process has a wide range of applications, high process maturity, strong equipment feasibility, and thus low costs.

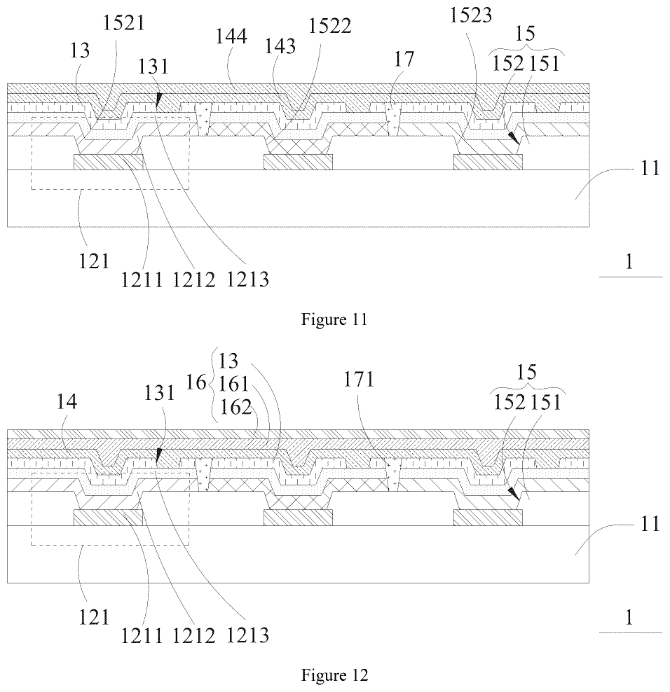

In one embodiment, as shown in FIG. 11, FIG. 11 is another cross-sectional view along line P-P′ in FIG. 2. The conductive layer 14 includes a first layer 143 and a second layer 144 stacked in a direction away from the substrate 11, the first layer 143 being formed by an evaporation coating process and the second layer 144 being formed by a vacuum coating process.

The first layer 143 may be made of silver or a mixture of silver and magnesium. The preparation process for the first layer 143 may use an evaporation coating process, which has a minimal impact on the second electrode 1213. At the same time, the first layer 143 may form a protective layer for protecting the second electrode 1213, reducing the damage to the second electrode 1213 caused during the preparation of the second layer 144 by the vacuum coating process.

In one embodiment, the conductive layer 14 includes the first layer 143 and the second layer 144 which are stacked, which helps to further reduce the internal impedance of the drive circuit.

In one embodiment, the first layer 143 and the second layer 144 can be patterned simultaneously, thereby saving the preparation process. During the patterning process, the protective layer 13 acts as a barrier, resulting in a higher yield.

In one embodiment, as shown in FIG. 12, FIG. 12 is another cross-sectional view along line P-P′ in FIG. 2. The display panel 1 further includes an encapsulation layer 16, the encapsulation layer 16 being located on a side of the light-emitting layer 12 facing away from the substrate 11, and the encapsulation layer 16 including the protective layer 13, a first encapsulation layer 161, and a second encapsulation layer 162.

In one embodiment, the protective layer 13 is an inorganic layer and is also used as a layer of the encapsulation layer 16, which contributes to saving preparation processes and making the display panel 1 lighter and thinner. The encapsulation layer 16 further includes a first encapsulation layer 161 and a second encapsulation layer 162, which are sequentially formed on the side of the protective layer 13 facing away from the substrate 11. The first encapsulation layer 161 may be made of an organic material, and the second encapsulation layer 162 may be made of an inorganic material. Inorganic materials have strong moisture and oxygen isolation properties, while organic materials offer better fluidity and flatness. The encapsulation layer 16, which is stacked by an inorganic material layer, an organic material layer and an inorganic layer material layer, can further enhance the encapsulation effect, thereby improving the reliability of the light-emitting unit 121.

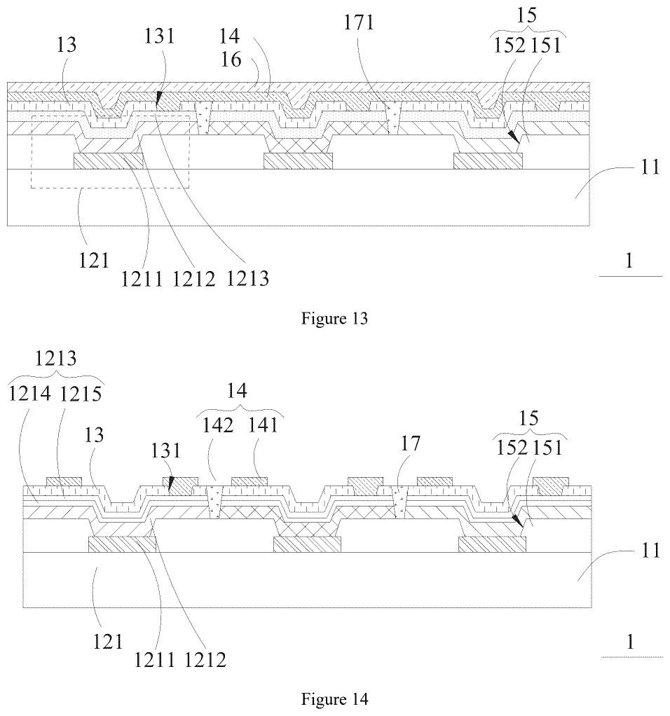

In one embodiment, as shown in FIG. 13, FIG. 13 is another cross-sectional view along line P-P′ in FIG. 2. The encapsulation layer 16 is located on the side of the protective layer 13 facing away from the substrate 11.

In one embodiment, the encapsulation layer 16 is formed on the side of the protective layer 13 facing away from the substrate 11, and the encapsulation layer 16 includes an inorganic material layer, an organic material layer and an inorganic layer material layer which are stacked, that is, an inorganic material layer is superimposed on the protective layer 13 to improve the encapsulation effect.

In one embodiment, the second electrode 1213 may be typically made of a mixture of silver and magnesium and is prepared using an evaporation coating process, which has a minimal impact on the underlying light-emitting functional layer 1212 and contributes to improving the yield of the light-emitting unit 121.

In one embodiment, as shown in FIG. 14, FIG. 14 is another cross-sectional view along line P-P′ in FIG. 2. The second electrode 1213 is made of a metal layer 1214 and a transparent conductive layer 1215 located on a side of the metal layer 1214 facing away from the substrate 11.

In one embodiment, the transparent conductive layer may be made of a metal oxide layer, including indium tin oxide, indium zinc oxide, etc., which is not particularly limited in the present application. The transparent conductive layer is in direct contact with the second electrode 1213. Moreover, when a through hole or a conductive layer is prepared in or on the protective layer 13, the transparent conductive layer can protect the metal layer, thereby reducing damage to the metal layer in subsequent processing steps. In addition, the transparent conductive layer and the metal layer are stacked layer on layer to form a composite electrode, which can reduce the resistance of the drive circuit, thereby improving the display effect.

The preparation process for the transparent conductive layer may use a physical vapor deposition (PVD) or atomic layer deposition (ALD) process, which is not particularly limited in the present application.

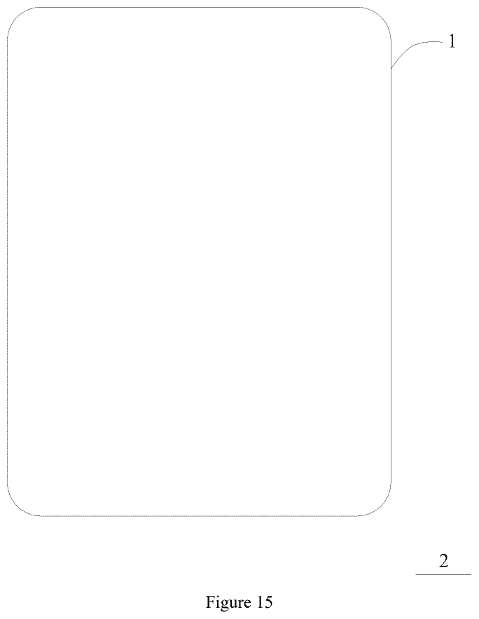

The present application further provides a display apparatus 2. As shown in FIG. 15, FIG. 15 is a structural schematic diagram of a display apparatus according to an embodiment of the present application. The display apparatus 2 includes any one of the display panels 1 according to the above embodiments. The display apparatus offers better display uniformity and improved display quality.

The display apparatus 2 may be a mobile terminal, such as a mobile phone or a notebook computer, a fixed terminal, such as a television or a computer monitor, or a wearable device, such as a smartwatch, which is not particularly limited in the present application.

The embodiments of the present application as described above neither set forth all the details, nor do they limit the present application to the embodiments described. Apparently, various modifications and variations can be made in light of the above description. The embodiments are selected and described in this specification to better explain the principles and practical applications of the present application, and good use of the present application and modify and use the present application on the basis of the present application. The present application is limited only by the claims and all the scopes and equivalents thereof.

What is claimed is:

1. A display panel, comprising:
a substrate;
a light-emitting layer formed on a side of the substrate and comprising a plurality of light-emitting units, each of the light-emitting units comprising a first electrode, a light-emitting functional layer and a second electrode stacked in a direction away from the substrate;
a protective layer formed on a side of the second electrode facing away from the substrate; and
a conductive layer formed on a side of the protective layer facing away from the second electrode, the conductive layer being electrically connected to the second electrode.

2. The display panel of claim 1, wherein the light-emitting layer comprises first light-emitting unit groups, each of the first light-emitting unit groups comprising the light-emitting units of at least three colors, and the conductive layer being electrically connected to the second electrode through a first via running through the protective layer.

3. The display panel of claim 2, wherein the number of the first vias corresponding to each first light-emitting unit group is the same.

4. The display panel of claim 2, wherein an orthographic projection of the second electrode on the substrate partially covers the substrate, and the conductive layer comprises a body portion and a light-transmitting portion, the light-transmitting portion corresponding to the light-emitting units and being configured to transmit light emitted by the light-emitting units.

5. The display panel of claim 1, wherein the light-emitting layer comprises second light-emitting unit groups, each of the second light-emitting unit groups comprises a plurality of light-emitting units, colors of the light-emitting units of the second light-emitting unit group are the same, and the number of first vias corresponding to different second light-emitting unit groups is different.

6. The display panel of claim 1, wherein the second electrodes of the adjacent light-emitting units are spaced apart; the conductive layer comprises a body portion and a light-transmitting portion, the light-transmitting portion corresponding to the light-emitting units and being configured to transmit light emitted by the light-emitting units; and the body portion is electrically connected to the second electrode through first vias running through the protective layer, the first vias corresponding to the second electrodes on a one-to-one basis.

7. The display panel of claim 6, wherein the body portion overlaps an edge of the second electrode, and the body portion and the second electrode are electrically connected.

8. The display panel of claim 6, further comprising:
a pixel defining layer which is formed on a side of the first electrode facing away from the substrate and comprises a pixel defining portion and a plurality of pixel openings, the pixel openings each being configured to expose the first electrode, and the light-emitting units corresponding to the pixel openings on a one-to-one basis; and
an isolation structure formed on a side of the pixel defining portion facing away from the substrate, the isolation structure being positioned between two adjacent ones of the pixel openings.

9. The display panel of claim 8, wherein in a first cross section of the isolation structure along a thickness direction of the display panel, a length of an end of the isolation structure away from the substrate is greater than that of an end of the isolation structure close to the substrate.

10. The display panel of claim 9, wherein the first cross section of the isolation structure along the thickness direction of the display panel is rectangular, upright trapezoidal, or inverted trapezoidal in shape.

11. The display panel of claim 6, wherein the display panel further comprises a pixel defining layer formed on a side of the first electrode facing away from the substrate, wherein the pixel defining layer comprises a pixel defining portion and a plurality of pixel openings, the pixel openings each being configured to expose the first electrode, and the light-emitting units corresponding to the pixel openings on a one-to-one basis; an isolation gap is formed between adjacent ones of the light-emitting units; the isolation gap exposes part of the pixel defining portion; an orthographic projection of the protective layer on the substrate does not overlap with an orthographic projection of the isolation gap on the substrate; and the body portion extends into the isolation gap.

12. The display panel of claim 11, wherein the body portion extends into the isolation gap and contacts an edge of the second electrode.

13. The display panel of claim 1, wherein the conductive layer comprises a body portion and a light-transmitting portion, the light-transmitting portion corresponding to the light-emitting units and being configured to transmit light emitted by the light-emitting units; and the light-transmitting portion is integrally and consecutively formed with the body portion, and the conductive layer is made of a transparent conductive material.

14. The display panel of claim 1, wherein the conductive layer comprises a body portion and a light-transmitting portion, the light-transmitting portion corresponding to the light-emitting units and being configured to transmit light emitted by the light-emitting units; and the light-transmitting portion comprises a through hole running through the body portion along a thickness direction of the body portion, and the through hole is configured to transmit light emitted by the light-emitting unit.

15. The display panel of claim 14, wherein the conductive layer is made of at least one of a metal and a transparent metal oxide material.

16. The display panel of claim 1, wherein the conductive layer comprises a first layer and a second layer stacked in a direction away from the substrate, the first layer being formed by an evaporation coating process, and the second layer being formed by a vacuum coating process.

17. The display panel of claim 1, wherein the display panel further comprises an encapsulation layer, wherein the encapsulation layer is located on a side of the light-emitting layer facing away from the substrate and comprises the protective layer, a first encapsulation layer, and a second encapsulation layer; or
the encapsulation layer is located on a side of the protective layer facing away from the substrate.

18. The display panel of claim 1, wherein the second electrode is made of a metal layer and a transparent conductive layer located on a side of the metal layer facing away from the substrate.

19. A display apparatus, comprising:
a display panel, comprising:
a substrate;
a light-emitting layer formed on a side of the substrate and comprising a plurality of light-emitting units, each of the light-emitting units comprising a first electrode, a light-emitting functional layer and a second electrode stacked in a direction away from the substrate;
a protective layer formed on a side of the second electrode facing away from the substrate; and
a conductive layer formed on a side of the protective layer facing away from the second electrode, the conductive layer being electrically connected to the second electrode.

20. A preparation method for a display panel, comprising:
providing a substrate;
forming a light-emitting layer on a side of the substrate, the light-emitting layer comprising a plurality of light-emitting units, wherein each of the light-emitting units comprises a first electrode, a light-emitting functional layer and a second electrode stacked in a direction away from the substrate;
forming a protective layer on a side of the second electrode facing away from the substrate; and
forming a conductive layer on a side of the protective layer facing away from the second electrode, the conductive layer being electrically connected to the second electrode.
